(19) United States
(12) Patent Application Publication
(10) Pub. No.: US 2024/0247403 A1
(43) Pub. Date: Jul. 25, 2024

(54) Method and Apparatus for Single Crystal Growth, and Single Crystal

(71) Applicant: XUZHOU XINJING SEMICONDUCTOR TECHNOLOGY CO., LTD, Xuzhou, Jiangsu (CN)

(72) Inventors: Shuangli WANG, Xuzhou, Jiangsu (CN); Chun-hung CHEN, Taiwan (CN); Chenguang SUN, Xuzhou, Jiangsu (CN)

(21) Appl. No.: 18/289,890

(22) PCT Filed: Jun. 22, 2022
(86) PCT No.: PCT/CN2022/100291

§ 371 Date: Nov. 7, 2023

(30) Foreign Application Priority Data
Jun. 25, 2021 (CN) 202110712578.X

(51) Int. Cl. C30B 15/20; C30B 29/06

(52) U.S. Cl. CPC C30B 15/203; C30B 29/06

(57) ABSTRACT

Provided are a method and apparatus for single crystal growth, and a single crystal. The method includes: determining a V/G window range that can produce a perfect crystal according to a V/G theory; obtaining a crystal growth rate V, and obtaining a range of a temperature gradient G at a solid-liquid interface for crystal growth; and obtaining a single crystal by determining a gap d or a crystal bar radius r according to the range of the temperature gradient G and a function F(d, r) of the gap d and the crystal bar radius r.

### CROSS-REFERENCE TO RELATED APPLICATION

The present disclosure claims the priority of Chinese patent application No. 202110712578.X, filed with China National Intellectual Property Administration on Jun. 25, 2021 and entitled “Method and Apparatus for Single Crystal Growth, and Single Crystal”, the entire contents of which are incorporated herein by reference.

### TECHNICAL FIELD

The disclosure relates to the field of semiconductors, in particular to a method and apparatus for single crystal growth, and a single crystal.

### BACKGROUND

During single crystal growth by Czochralski method, a temperature gradient G at a solid-liquid interface for crystal growth is intimately bound up with a thermal stress distribution. Generally, the greater the temperature gradient is, the greater a thermal stress is, and the more crystal defects will be produced. Under certain thermal field conditions for crystal growth, the temperature gradient G at the solid-liquid interface for crystal growth is closely tied to a gap d and a crystal growth rate. Based on Voronkov's theory, types and densities of the crystal defects are associated with a V/G value (V is the crystal growth rate and G is the temperature gradient at the solid-liquid interface) at the solid-liquid interface for crystal growth, and the V/G value can be used to determine a boundary of a region where point defects occur.

Since the crystal growth rate V keeps substantially unchanged at a equal diameter stage for crystal growth, conditions for pulling perfect crystals can be satisfied only by properly controlling the temperature gradient G at the solid-liquid interface, that is, keeping the V/G value within a certain range.

However, during actual production, the crystal growth rate, which is easy to measure, approximately equals a crystal pulling rate while the temperature gradient G at the solid-liquid interface for crystal growth, which is complicated to compute, cannot be directly measured. Therefore, an existing method and apparatus for single crystal growth, and existing single crystal silicon still need to be improved.

### SUMMARY

According to one aspect of the disclosure, the disclosure provides a method for single crystal growth. The method includes: a V/G window range that may produce a perfect crystal is determined according to a V/G theory; a crystal growth rate V is obtained, and a range of a temperature gradient G at a solid-liquid interface for crystal growth is obtained; and a single crystal is obtained by determining a gap d or a crystal bar radius r according to the range of the temperature gradient G and a function F(d, r) of the gap d and the crystal bar radius r for the temperature gradient G.

The function of the gap d and the crystal bar radius r for the temperature gradient G is determined as follows: global simulation computation is performed on heat and mass transfer during crystal growth by Czochralski method at a equal diameter stage, and temperature gradient distributions at solid-liquid interfaces for crystal growth at a plurality of different gaps are obtained separately, where the plurality of different gaps are a plurality of preset distances; a function of the crystal bar radius r for the temperature gradients G at different gaps is obtained separately according to the temperature gradient distributions at the solid-liquid interfaces for crystal growth at the plurality of different gaps; according to the plurality of different gaps and a parameter in a temperature gradient function corresponding to different gaps, a function of the gaps d for the parameter is obtained separately, and the function F(d, r) of the gap d and the radius r for the temperature gradient G is determined, where the gap is an interval between a lower end of a shield and a solid-liquid interface, the temperature gradient is an axial temperature gradient at the solid-liquid interface, and r is a crystal bar radius at the equal diameter stage.

According to an instance of the disclosure, the step that the global simulation computation is performed on heat and mass transfer during the crystal growth by the Czochralski method includes: a two-dimensional numerical-simulation Czochralski method crystal growth model is built according to a thermal field structure of a Czochralski method crystal growth furnace, and the temperature gradient distributions at the solid-liquid interfaces for crystal growth at the plurality of different gaps are computed and obtained at a set target crystal growth speed, where the two-dimensional Czochralski method crystal growth model includes crystal growth device parameters and process parameters determined according to a set target crystal growth speed.

According to an instance of the disclosure, the device parameters includes a quartz crucible, a shield, at least one heater and at least one heat preservation component that are added to the model; or the device parameters includes a graphite crucible, a shield, at least one heater and at least one heat preservation component that are added to the model; the process parameters include a charging amount, a rotation speed of a crucible and a rotation speed of a crystal bar; the step that the temperature gradient distributions at the solid-liquid interfaces for crystal growth at the plurality of different gaps are computed and obtained includes: a geometric model grid of a single crystal furnace is divided to grids, where the grids includes quadrilateral grids, triangular grids and one-dimensional grids configured to perform thermal radiation computation; silicon liquid and gas convection during crystal growth is computed based on Reynolds-averaged Navier-Stokes equations, and heat exchange for crystal growth by Czochralski method is computed based on Navier-Stokes equations, a heat conservation equation and a view factor radiation heat exchange method; and a Czochralski method crystal growth variable is stored in a center of a grid cell with a finite volume method, a control equation is solved with a discretization method, and the set target crystal growth speed is reached by adjusting power of a heater with a PID algorithm.

According to an instance of the disclosure, the step that the gap d or the crystal bar radius r is determined includes: under the condition that the gap d is a constant value, a value range of the crystal bar radius r is determined according to the function F(d, r) and the range of the temperature gradient G, and the crystal bar radius r at the equal diameter stage of the crystal keeps within the value range determined.

According to an instance of the disclosure, the step that the crystal bar radius r at the equal diameter stage of the crystal keeps within the value range determined is implemented by adjusting a crystal growth rate of a crystal bar.

According to an instance of the disclosure, under the condition that the crystal bar radius r is a constant value, a value range of the gap d is determined according to the function F(d, r) and the range of the temperature gradient G, and the gap d at the equal diameter stage of the crystal keeps within the value range determined.

According to an instance of the disclosure, the step that the gap d at the equal diameter stage of the crystal keeps within the value range determined is implemented by adjusting the interval between the lower end of the shield and the solid-liquid interface.

According to an instance of the disclosure, the function of the crystal bar radius r for the temperature gradient G is obtained as follows:

$$G = ( a , r ) ,$$

where a is a parameter related to the gap d, and the step that the function is obtained further includes: values of a at different gaps is determined.

According to an instance of the disclosure, the function of the crystal bar radius r for the temperature gradient G is a polynomial as follows:

$$G = {a}_{y} \cdot {r}^{( y - 1 )} + {a}_{( y - 1 )} \cdot {r}^{( y - 2 )} + {a}_{( y - 2 )} \cdot {r}^{( y - 3 )} + … + {a}_{( y - x + 1 )} \cdot {r}^{( y - x )} + a ,$$

where y is a positive integer greater than 1, and x=y−1.

According to an instance of the disclosure, the function of the gap d for a parameter a is as follows:

$$a = ( b , d ) ,$$

where b is a second parameter independent of the gap, and the step that the function of the gap d for a parameter a is obtained includes: values of b corresponding to different gaps are determined according to the values of a at different gaps and the gap.

According to an instance of the disclosure, the function of the gap (d) is a polynomial as follows:

$$a ( i ) = {b}_{p} \cdot {d}^{( p - 1 )} + {b}_{( p - 1 )} \cdot {d}^{( p - 2 )} + {b}_{( p - 2 )} \cdot {d}^{( p - 3 )} + … + {b}_{( p - q + 1 )} \cdot {d}^{( p - q )} + b ,$$

where p is a positive integer greater than 1, q=p−1, i is a positive integer ranging from y to 1, a coefficient b is a constant independent of the gap, and the coefficient b in the polynomial varies as i changes in value.

According to an instance of the disclosure, before the step that the function of the crystal bar radius r for the temperature gradients G with the plurality of different gaps is obtained, the method for single crystal growth further includes: a number of terms of the polynomial of the crystal bar radius r is determined according to a coefficient of determination of the temperature gradient function.

According to an example of the disclosure, a number of terms of the polynomial of F(d, r) is determined to make the coefficient of determination not smaller than 0.93. Based on that, accuracy of the function F(d, r) determined through the method can be further improved.

According to an instance of the disclosure, a number of the plurality of gaps is not less than 5.

According to another aspect of the disclosure, the disclosure provides an apparatus for single crystal growth. The apparatus includes: a furnace body, where an inner side of the furnace body is provided with an insulation layer; a crucible, where the crucible is arranged in the furnace body and defines an accommodation space; a shield, where the shield is arranged in the furnace body and above the crucible, and is configured to shield a crystal from heat; a heater, where the heater is arranged between the crucible and the insulation layer; a pulling apparatus, where the pulling apparatus is configured to control a crystal growth rate of a crystal bar; and a control system, where the control system is configured to determine a temperature gradient at a solid-liquid interface for crystal growth according to the method described above, and determine a gap and/or a crystal bar radius; where the gap is an interval between a lower end of the shield and the solid-liquid interface.

According to yet another aspect of the disclosure, the disclosure provides a single crystal. The single crystal is prepared through the method described above.

### BRIEF DESCRIPTION OF THE DRAWINGS

FIG. 1 shows a schematic flowchart of a method according to an instance of the disclosure;

FIG. 2 shows a schematic partial flowchart of a method according to an instance of the disclosure;

FIG. 3 shows a schematic structural diagram of an apparatus for single crystal growth according to an instance of the disclosure;

FIG. 4 shows a fitted polynomial and simulation computation curve between a temperature gradient with a gap of 40 mm and a radius according to an instance of the disclosure;

FIG. 5 shows a fitted polynomial and simulation computation curve between a temperature gradient with a gap of 42.5 mm and a radius according to an instance of the disclosure;

FIG. 6 shows a fitted polynomial and simulation computation curve between a temperature gradient with a gap of 45 mm and a radius according to an instance of the disclosure;

FIG. 7 shows a fitted polynomial and simulation computation curve between a temperature gradient with a gap of 47.5 mm and a radius according to an instance of the disclosure;

FIG. 8 shows a fitted polynomial and simulation computation curve between a temperature gradient with a gap of 50 mm and a radius according to an instance of the disclosure;

FIG. 9 shows a fitted polynomial and simulation computation curve between a temperature gradient with a gap of 52.5 mm and a radius according to an instance of the disclosure;

FIG. 10 shows a fitted polynomial and simulation computation curve between a temperature gradient with a gap of 55 mm and a radius according to an instance of the disclosure;

FIG. 11 shows a fitted polynomial and simulation computation curve between a temperature gradient with a gap of 57.5 mm and a radius according to an instance of the disclosure;

FIG. 12 shows a fitted polynomial and simulation computation curve between a temperature gradient with a gap of 60 mm and a radius according to an instance of the disclosure;

FIG. 13 shows a curve of a₇ with respect to a gap d according to an instance of the disclosure;

FIG. 14 shows a curve of a₈ with respect to a gap d according to an instance of the disclosure;

FIG. 15 shows a curve of a₅ with respect to a gap d according to an instance of the disclosure;

FIG. 16 shows a curve of a₄ with respect to a gap d according to an instance of the disclosure;

FIG. 17 shows a curve of a₃ with respect to a gap d according to an instance of the disclosure;

FIG. 18 shows a curve of a₂ with respect to a gap d according to an instance of the disclosure;

FIG. 19 shows a curve of a with respect to a gap d according to an instance of the disclosure;

FIG. 20 shows a simulated value, fitted value and polynomial curve of a temperature gradient at an interface for crystal growth at a gap of 45 mm;

FIG. 21 shows a simulated value, fitted value and polynomial curve of a temperature gradient at an interface for crystal growth at a gap of 50 mm;

FIG. 22 shows a simulated value, fitted value and polynomial curve of a temperature gradient at an interface for crystal growth at a gap of 55 mm.

### DETAILED DESCRIPTION OF THE EMBODIMENTS

The instances of the disclosure will be described in detail below, and are shown in accompanying drawings. The instances in the disclosure and features in the instances can be combined with one another if there is no conflict. The instances described below with reference to the accompanying drawings are illustrative and are merely used to explain the disclosure, but cannot be construed as limitation to the disclosure.

In the disclosure, unless otherwise specified, the following terms and symbols are defined as follows:

The gap d is an interval between a lower end of a shield and a solid-liquid interface. The symbol r denotes a crystal bar radius. The symbol V denotes a crystal growth rate of a crystal bar. The symbol G denotes a temperature gradient at a solid-liquid interface, specifically an axial temperature gradient at the solid-liquid interface, more specifically a temperature change amount of temperature T to 1412° C. per unit time.

The term “perfect crystal” or “defect-free crystal” used in this text does not mean an absolutely perfect crystal or a crystal without any defects, but allows a very small amount of one or more types of defects that are not enough to cause a great change in some electrical or mechanical features of a crystal or a wafer obtained and further result in deterioration of a performance of an electronic device composed of the crystal or wafer.

Czochralski method is used for single crystal growth. According to a V/G theory of the perfect crystal, a V/G window range is within 0.92-1.1 of (V/G)_{crit}, where (V/G)_{crit}=2.1*10⁻⁵ cm²·s⁻¹·k⁻¹. At a equal diameter stage, a crystal growth rate V of the crystal bar is constant, and merely a temperature gradient G is controlled. The temperature gradient G cannot be measured directly, and the temperature gradient G at the solid-liquid interface can be estimated merely through an indirect method. At present, if merely a qualitative relation between the gap d and the temperature gradient G is known, a quantitative relation between the gap d and the temperature gradient G cannot be determined. In view of the above problem, the applicant provides a method for single crystal growth. The method for single crystal growth includes: a temperature gradient at a solid-liquid interface is determined.

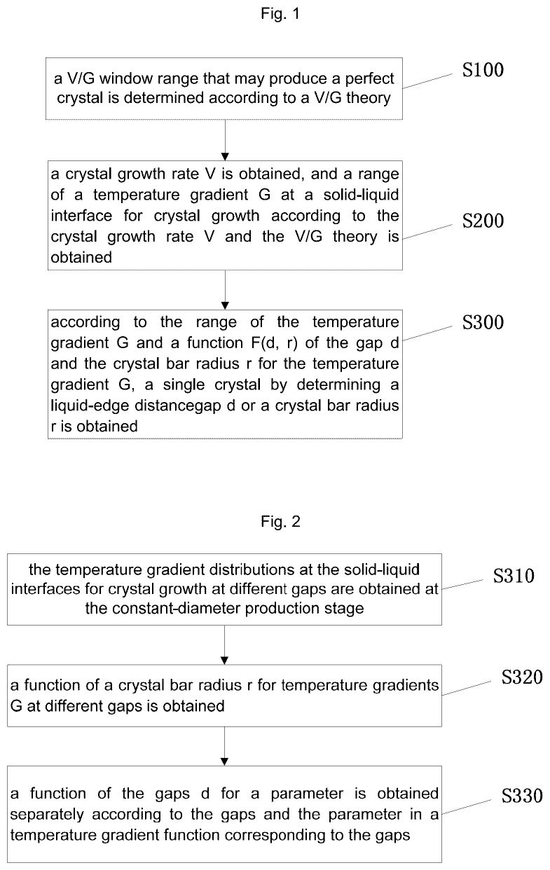

Specifically, with reference to FIG. 1, the method includes:

S100: a V/G window range that may produce a perfect crystal is determined according to a V/G theory.

According to the instance of the disclosure, in the step, the V/G window range that may produce the perfect crystal is determined according to the V/G theory.

Specifically, as mentioned above, a type and density of a point defect are related to V/G at the solid-liquid interface for crystal growth. Based on that, the V/G window range of the perfect crystal growth may be determined according to the V/G theory. For example, according to some specific instances of the disclosure, the V/G window range may be within 0.92-1.1 of (V/G)_{crit}, where (V/G)_{crit}=2.1.10⁻⁵ cm²·s⁻¹·k⁻¹. Based on that, the V/G window range that may produce the perfect crystal may be obtained, such that parameters of single crystal growth may be determined according to the V/G window range in the subsequent steps.

S200: a crystal growth rate V is obtained, and a range of a temperature gradient G at a solid-liquid interface for crystal growth according to the crystal growth rate V and the V/G theory is obtained.

According to the instance of the disclosure, in the step, a crystal growth rate V is obtained, and the range of the temperature gradient G at the solid-liquid interface for crystal growth are obtained at the equal diameter state according to the V/G window range obtained in the previous step.

Specifically, during crystal growth, usable crystals may be obtained at the equal diameter stage, and the crystal growth rate V of the crystal bar is basically constant at the equal diameter stage. Based on that, according to the previous V/G window range, a range value that the temperature gradient G needs to reach at the equal diameter stage is obtained.

S300: according to the range of the temperature gradient G and a function F(d, r) of the gap d and the crystal bar radius r for the temperature gradient G, a single crystal by determining a gap d or a crystal bar radius r is obtained.

Wherein, the distance between a lower end of a shield and a solid-liquid interface is called the gap, the temperature gradient G denotes a temperature change amount of temperature T to 1412° C. per unit time, specifically an axial temperature gradient at the solid-liquid interface.

According to the instance of the disclosure, in the step, the perfect crystal is produced by determining the gap d or the crystal bar radius r according to the range of the temperature gradient G and the function F(d, r) of the gap d and the crystal bar radius r for the temperature gradient G.

Specifically, in the step, the function F(d, r) of the gap d and the crystal bar radius r for the temperature gradient G is determined at first. With reference to FIG. 2, the function of the gap d and the crystal bar radius r for the temperature gradient G may be determined as follows:

S310: the temperature gradient distributions at the solid-liquid interfaces for crystal growth at different gaps are obtained at the equal diameter production stage.

According to the instance of the disclosure, in the step, global simulation computation is performed on heat and mass transfer during crystal growth by Czochralski method, and the temperature gradient distributions at the solid-liquid interfaces for crystal growth at the plurality of different gaps are obtained. The plurality of different gaps are a plurality of preset distances.

Specifically, a geometric model grid of a single crystal furnace is divided to grids, where the grids includes quadrilateral grids, triangular grids and one-dimensional grids configured to perform thermal radiation computation.

Specifically, according to the instance of the disclosure, the step that global simulation computation is performed on heat and mass transfer during crystal growth by Czochralski method may include: a two-dimensional numerical-simulation Czochralski method crystal growth model is built according to a thermal field structure of a Czochralski method single crystal furnace, where the two-dimensional Czochralski method crystal growth model built includes crystal growth device parameters by Czochralski method and process parameters determined according to a target crystal growth rate set. Based on that, the temperature gradient distributions at the solid-liquid interfaces for crystal growth at different gaps may be obtained at the set target crystal growth speed.

Heat and mass transfer is included during the Czochralski method single crytal growth. Mass transfer includes gas convection mass transfer and convection mass transfer in a silicon liquid, and gas convection of the silicon liquid during crystal growth can be computed based on Reynolds-averaged Navier-Stokes equations. Heat transfer includes heat conduction of contact components, heat radiation of non-contact components and heat convection in the silicon liquid and gas. Based on Navier-Stokes equations, a heat conservation equation and a view factor radiation heat transfer method, the heat exchange for crystal growth by Czochralski method is computed. A Czochralski method crystal growth variable is stored in a center of a grid cell with a finite volume method, a control equation is solved with a discretization method, and the set target crystal growth speed is reached by adjusting power of a heater with a PID algorithm. Based on the above control equation and algorithm, global simulation computation is performed on the heat and mass transfer during crystal growth by Czochralski method, and the temperature gradient distribution at the solid-liquid interface for crystal growth by Czochralski method is obtained. Based on that, the temperature gradient distributions at the solid-liquid interfaces for crystal growth at different gaps can be obtained accurately.

According to the instance of the disclosure, the crystal growth device parameters and the process parameters are set for the two-dimensional Czochralski method crystal growth model. Types of the device parameters may be determined according to a specific structure of a crystal growth device. For example, components such as a quartz crucible, a shield, at least one heater, a pulling apparatus and at least one heat preservation component may be added to the model, or the components such as a graphite crucible, the shield, the at least one heater, the pulling apparatus and the at least one heat preservation component may be added to the model. The process parameters may be determined according to an actual production process, and may include, for example, a charging amount, a rotation speed of a crucible, a crystal bar rotation speed, a pulling rate, etc.

For example, according to some specific instances of the disclosure, crystal growth simulator (CGSIM) software may be used to simulate a thermal field distribution in a Czochralski single crystal furnace in the step. Under the conditions of a certain crystal growth rate V and a certain gap d, simulation results are extracted to obtain the temperature gradient of the solid-liquid interface for crystal growth and the crystal bar radius, and a trend line of the temperature gradient changing in a radial direction may be further obtained. By repeating the above process many times and changing a simulated value of d, the temperature gradient distributions at the solid-liquid interfaces for crystal growth at different gaps can be obtained.

According to the instance of the disclosure, the crystal growth rate during simulation in the step is not particularly limited, and can be determined by those skilled in the art according to actual requirements. The crystal growth rate of 0.4 mm/min-0.55 mm/min may be selected for simulation, such as 0.4 mm/min, 0.42 mm/min, 0.45 mm/min, 0.5 mm/min, 0.53 mm/min and 0.55 mm/min.

Those skilled in the art can understand that during actual production, a production apparatus, such as a single crystal growth apparatus, specifically, hardware such as the furnace body, the heater and the heat preservation component for crystal growth is mounted and determined, a thermal field provided by the furnace body is determined. As a result, for a certain production apparatus, the above global simulation process is required to be performed once for obtaining the trend line of temperature gradient changing in the radial direction at a certain crystal growth rate V and different gaps d in the case of the thermal field distribution in a furnace.

According to the instance of the disclosure, specific values of the plurality of preset gaps are not particularly limited, and can be selected by those skilled in the art according to device conditions and the requirements of the crystal bar. Since the trend line of the temperature gradient changing in the radial direction with a plurality of specific gaps obtained in the step will be used to determine the function F(d, r) in subsequent steps, the more gaps are simulated, the higher accuracy of the function F(d, r) will be. However, repeated simulation is laborious, and those skilled in the art can determine a number of simulation computations in the step according to specific requirements. For example, according to some specific instances of the disclosure, the number of simulation computations, that is, a number of the plurality of preset gaps, may be not less than 5. Based on that, accuracy of the method can be further improved. More specifically, nine sets of simulation data may be used for subsequent operations. Specifically, the specific values of the gap d may be 40 mm, 42.5 mm, 45 mm, 47.5 mm, 50 mm, 52.5 mm, 55 mm, 57.5 mm and 60 mm, totaling nine sets of data.

S320: a function of a crystal bar radius r for temperature gradients G at different gaps is obtained.

According to the instance of the disclosure, in the step, the function F (d, r) of the crystal bar radius (r) for the temperature gradients G at different gaps is obtained separately according to the above temperature gradient distributions at the solid-liquid interfaces for crystal growth at the plurality of different gaps.

Specifically, in the step, the function of the crystal bar radius r for the temperature gradient G may be obtained at first according to the trend lines of the temperature gradient changing in the radial direction with the plurality of gaps obtained in the previous operation:

$$G = ( a , r )$$

where a is a parameter related to the gap. In the step, an operation of determining values of a at different gaps may be further included.

Specifically, the function of the crystal bar radius r for the temperature gradient G is a polynomial of the crystal bar radius r. According to a specific instance of the disclosure, the polynomial may be expressed as follows:

$$G = {a}_{y} \cdot {r}^{( y - 1 )} + {a}_{( y - 1 )} \cdot {r}^{( y - 2 )} + {a}_{( y - 2 )} \cdot {r}^{( y - 3 )} + … + {a}_{( y - x + 1 )} \cdot {r}^{( y - x )} + a \qquad ( I )$$

where y is a positive integer greater than 1, and x=y−1. Values of coefficients (that is, ay-a) in the temperature gradient function may vary or keep constant at different gaps. The above formula (I) is fitted based on the trend lines of the temperature gradients changing in the radial direction obtained at different gaps, a polynomial with degree y−1 of r may be obtained, and specific values of a plurality of coefficients in the above formula (I) may be obtained.

The inventor finds that the value of the coefficient a (ay-a) in the above formula (I) may be expressed as a function merely related to the gap d. That is to say, since the coefficient a in the above formula (I) has nothing to do with the radius r, in the subsequent steps, after determining a relation between the coefficient a and the gap by fitting, it can be simply concluded that the temperature gradient G is a function only related to the gap d and the radius r.

Based on that, when the relation between the coefficient a and the gap d is determined, the method may determine the F(d, r) function of the gap d and the crystal bar radius r for the temperature gradient G by using the formula (I) and the relation between the coefficient a and the gap d. Under a certain thermal field and crystal growth rate, the radius r may be determined according to the gap and temperature gradient requirements, or the gap may be adjusted according to the temperature gradient requirements and the radius r. Then, a crystal growth process may be regulated and adjusted to obtain the temperature gradient of the V/G window range for producing the perfect crystal.

According to the instance of the disclosure, before the step that a function F(d, r) of the crystal bar radius (r) for the temperature gradients G at the plurality of different gaps is obtained, a number of terms of the polynomial of the crystal bar radius r may be determined at first according to a coefficient of determination of the temperature gradient function F(d, r). That is, in the step, the number of terms of the F(d, r) polynomial is determined, that is, a value of y in the previous x=y−1 is determined. Based on that, the correlation between the function F(d, r) determined through the method and the temperature gradient distribution determined through simulation computation can be further improved. Specifically, the coefficient of determination may be made not less than 0.93, and accuracy of the function F(d, r) determined through the method can be further improved. For example, specifically, the number of terms of the polynomial may be 6, that is, the above formula (I) may be expressed as:

$$G = {a}_{7} \cdot {r}^{6} + {a}_{6} \cdot {r}^{5} + {a}_{5} \cdot {r}^{4} + {a}_{4} \cdot {r}^{3} + {a}_{3} \cdot {r}^{2} + {a}_{2} \cdot r + a$$

The inventor finds that when F(d, r) is selected as a polynomial with degree six about r, the coefficient of determination is closer to 1. According to some other instances of the disclosure, when crystal growth conditions are not required to be strictly controlled, a polynomial with degree five or four may also be selected, which may be determined according to specific requirements of the coefficient of determination R².

Specifically, the trend lines of the temperature gradient changing in the radial direction at the plurality sets of gaps obtained in the previous step may be fitted to the function of the parameter a and the crystal bar radius r for the temperature gradient. Specifically, the above fitting may be performed to a polynomial conforming to the previous formula (I), and then specific values of the parameter a in formula (I) at different gaps may be obtained. For example, when the function is a polynomial, specific values of coefficients may be obtained. The value may be used in subsequent operations to determine the function of the gap for the coefficient a. The inventor finds that specific radial coordinates (that is, the R value) are plugged into the previous formula (I) of the coefficient of determination to obtain polynomial fitting computed values, and the obtained polynomial computed values may well coincide with the trend line obtained through simulation computation. In order to minimize a fitting error, reserved decimal places of specific values of fitted polynomial coefficients may be as many as possible. Specifically, a scientific counting method for the fitted polynomial coefficients indicates reservation to 10 decimal places. The more the reserved decimal places are, the higher the accuracy is, the smaller an error is. The computed temperature gradient is close to a simulated value of CGSIM software, and then, the reserved decimal places of a fitting coefficient may be adjusted according to accuracy requirements of the temperature gradient.

According to some specific instances of the disclosure, in order to further verify accuracy of the function of the crystal bar radius r for the temperature gradient G obtained in the step, the accuracy of the function G=(a, r) determined in the step may be verified before the subsequent step. Specifically, a software fitting curve, a polynomial curve and a computation curve may be compared to determine fitting accuracy of the function G=(a, r). Specifically, the software fitting curve may be a trend line obtained through simulation with CGSIM software, the polynomial curve may be a curve obtained through drawing according to the obtained function G=(a, r), and the computation curve may be a curve based on the temperature gradient obtained by plugging specific radial coordinates (that is, r value) into the function G=(a, r). It is indicated that a fitting effect is desirable if the three curves may overlap well.

S330: a function of the gaps d for a parameter is obtained separately according to the gaps and the parameter in a temperature gradient function corresponding to the gaps.

According to the instance of the disclosure, in the step, the function of the gaps d for the parameter is obtained separately according to the plurality of preset different gaps and the parameter in the temperature gradient function corresponding to different gaps.

Specifically, in the step, according to the plurality of preset different gaps and specific values of the parameter a in the function F(d, r) corresponding to the gaps determined in the previous step, the functions of the gaps d for the parameter a are separately obtained as follows:

$$a = ( b , d ) ,$$

where d is the gap, and b is a second parameter independent of the gap. When the gap varies, the value of b may keep constant or not. According to a specific instance of the disclosure, the function may also be a polynomial, the second parameter b may be a constant, and the function a=(b, d) may be expressed as follows:

$$a ( i ) = {b}_{p} \cdot {d}^{( p - 1 )} + {b}_{( p - 1 )} \cdot {d}^{( p - 2 )} + {b}_{( p - 2 )} \cdot {d}^{( p - 3 )} + … + {b}_{( p - q + 1 )} \cdot {d}^{( p - q )} + b \qquad ( II )$$

where p is a positive integer greater than 1, q=p−1, i is a positive integer ranging from y to 1, and a (1) is be shortened to a. The coefficient b is a constant independent of the radius. When i varies in value, the coefficient b in the polynomial may vary or not. Based on that, a correlation of the temperature gradient G at the interface for crystal growth at the gap d and the crystal growth rate V at a certain thermal field can be obtained without frequent complex simulation computation, and a correlation among a value of d, features of a radial distribution of the interface temperature gradient and a temperature gradient is simply determined, so as to quickly determine the gap d and the crystal bar radius r during the actual production.

With G=(a, r) and a=(b, d) as polynomials as examples, a(i) denotes a coefficient in the polynomial (G=(a, r)) determined above. If the polynomial is a polynomial with degree 6, a(i) includes a₇-a. As mentioned previously, the coefficient a may be expressed as a function merely related to the gap d, that is, a polynomial shown in the above formula (II). Based on that, after the above formula (II) is determined, a specific value of a coefficient a(i), such as a₇-a, may be obtained according to the specific gap. After the value is plugged into the previous formula (I), the radius r may be obtained according to requirements of the temperature gradient G, or the temperature gradient G corresponding to any radius r may be determined. Alternatively, according to the requirements of temperature gradient g and the radius r, the gap d in the above formula (II) may be obtained reversely, so as to control the crystal growth process or obtain the temperature gradient G.

According to the instance of the disclosure, similarly, before obtaining the polynomial of the coefficient ay-a with respect to the gap, the coefficient of the polynomial may also be determined at first according to the coefficient of determination of the polynomial. Based on that, accuracy of the polynomial of the coefficient ay-a with respect to the gap determined through the method can be further improved.

According to the instance of the disclosure, a value of p in q=p−1 defined previously and a value of y in the previous step may keep constant or not. That is, numbers of polynomial terms of Formula (I) and Formula (II) may be the same or different. According to some specific instances of the disclosure, the number of terms of the polynomial may be 6, that is, the above formula (I) may be expressed as follows:

$$a ( i ) = {b}_{7} \cdot {d}^{6} + {b}_{6} \cdot {d}^{5} + {b}_{5} \cdot {d}^{4} + {b}_{4} \cdot {d}^{3} + {b}_{3} \cdot {d}^{2} + {b}_{2} \cdot d + b .$$

That is to say, with the numbers of items of the polynomials Formula (I) and Formula (II) of 6 as an example, a coefficient a₁ of Formula (I) obtained at any gap may be expressed as the above formula (II) merely related to the gap d, and similarly, a₂ may also be expressed as the above formula (II) merely related to the gap d. However, coefficients b₇-b of a₁ may be different from coefficients b₇-b of a₂.

The applicant finds that when a(i) is a polynomial with degree six, the coefficient of determination of the polynomial is closer to 1. According to some other instances of the disclosure, when crystal growth conditions are not required to be strictly controlled, a polynomial with degree five or four may also be selected, which may be determined according to specific requirements of the coefficient of determination of a (i).

Based on that, the function of the gap d and the crystal bar radius r for the temperature gradient G may be simply determined. That is to say, after the production device is determined, the function of the gap d and the crystal bar radius r for the temperature gradient G at the equal diameter stage of the device may be obtained through the above operation. Then, according to the range of the temperature gradient G at the solid-liquid interface for crystal growth determined in the previous step, the gap d and/or the crystal bar radius r may be controlled, such that the production parameters for obtaining perfect crystals by using the production device may be simply determined.

According to some instances of the disclosure, the gap d may be set to a constant value, that is, the interval between the lower end of the shield and the solid-liquid interface in the apparatus keeps constant. That is, a value range of the crystal bar radius r may be determined according to the function F(d, r) and the range of the temperature gradient G obtained in the previous step. The crystal bar radius r at the equal diameter stage of the crystal keeps within the value range determined. Specifically, the crystal bar radius r may be controlled by adjusting the crystal growth rate of the crystal bar. At the equal diameter stage, the crystal growth rate of the crystal bar is slightly increased, and correspondingly, the crystal bar radius r is slightly reduced. Similarly, the crystal growth rate of the crystal bar is slightly reduced, and the crystal bar radius r is slightly increased. During practical production, a charge coupled device (CCD) or other existing measuring systems may be used to measure the crystal bar radius r.

In some other instance of the disclosure, especially when a size of a wafer is relatively constant as required by a client or a size of a crystal bar determined is unchanged, the crystal bar radius r may be kept a constant value, the value range of the gap d is determined according to the function F(d, r) and the range of the temperature gradient G, and the gap d at the equal diameter stage of the crystal may be kept within the value range determined. In this case, the gap d may be adjusted by adjusting the interval between the lower end of the shield and the solid-liquid interface. During actual production, CCD and/or laser is used to measure the gap d or other existing measurement components to measure the gap d. Based on that, the gap or the crystal bar radius r can be flexibly adjusted, thereby improving quality of the crystal produced through the method.

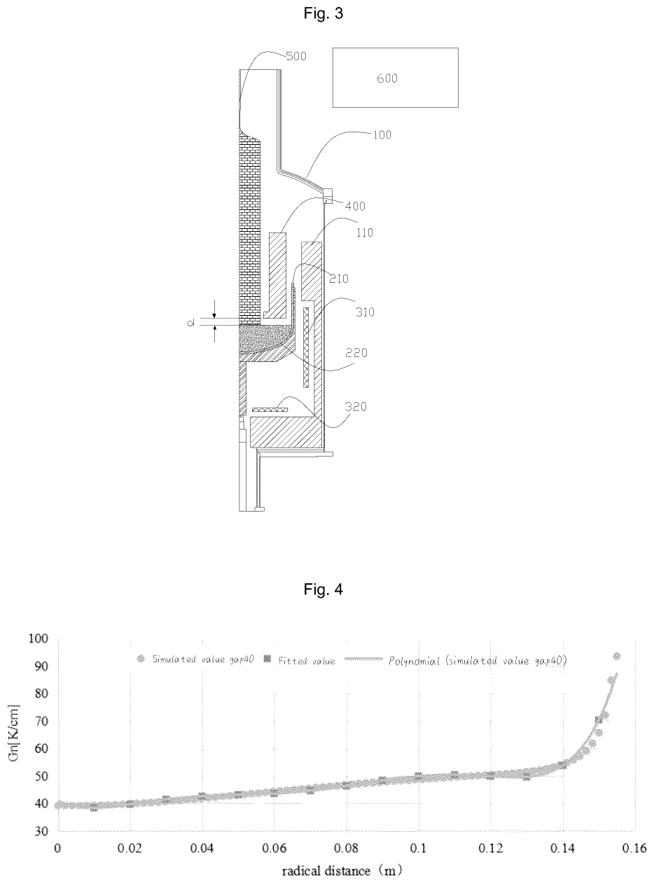

According to another aspect of the disclosure, the disclosure provides an apparatus for single crystal growth. With reference to FIG. 3, the apparatus includes: a furnace body 100, where an inner side of the furnace body 100 is provided with an insulation layer 110. A crucible is arranged in the furnace body 100 and defines an accommodation space. For example, the crucible may specifically include a quartz crucible 210 and a graphite crucible 220. A shield 400 is arranged in the furnace body and above the crucible, and is applied to thermal shielding of a crystal. A heater is arranged between the crucible and the insulation layer 110, and may specifically include, for example, a side heater 310 and a bottom heater 320. A pulling apparatus 500 is configured to control a crystal growth rate of a crystal bar, and control a crystal bar radius r by controlling the crystal growth rate of the crystal bar. A control system 600 is configured to determine a temperature gradient at a solid-liquid interface for crystal growth according to the method described previously, and determine a gap (such as d shown in the figure) and/or the crystal bar radius. Specifically, the control system 600 may also include a measurement unit. The measurement unit may have components including but not limited to, a CCD and a laser ranging component to measure and determine a current gap and crystal bar radius. The gap d is an interval between a lower end of the shield and the solid-liquid interface. After the control unit determines a required gap and/or crystal bar radius, through a relevant component in the control apparatus, the crystal growth rate of the crystal bar may be adjusted to make the crystal bar radius reach a value determined by the control system, or a distance between the shield and the solid-liquid interface is adjusted to make the gap d reach the value determined by the control system. Based on that, so as to adopt the above single crystal growth method and timely adjust the gap d or the crystal bar radius r through the control system to produce perfect crystals. Based on that, through the above method for single crystal growth, the gap d or the crystal bar radius r is timely adjusted through the control system, and the perfect crystal can be produced as a result. Therefore, quality of single crystal growth through the apparatus can be improved, and process parameters of the apparatus are easy to determine and an operation is more convenient.

Specifically, as mentioned previously, the control system 600 may obtain a V/G window range according to a V/G theory under a thermal field determined through the apparatus for single crystal growth according to the previous method. Then, the range of the temperature gradient G is determined according to a value of V at a equal diameter stage of the apparatus. Finally, a function F(d, r) of the gap d and the crystal bar radius r for the temperature gradient G is obtained through the previous method. In this case, when the crystal bar radius r is a constant value, the control system may compute and determine the gap d according to the function F(d, r), and control the distance d between the shield and the solid-liquid interface shown in FIG. 3. Thereby, crystal growth can be simply controlled and a perfect crystal can be obtained.

Alternatively, when the gap d of the apparatus is relatively fixed, the control system 600 may compute and determine the value of the crystal bar radius r according to the previous method.

Alternatively, when the gap d of the apparatus falls within a certain range, the control system 600 may compute and determine a range of the crystal bar radius r according to the previous method.

The system at least has the following advantages: growth conditions of a single crystal can be flexibly controlled. For example, when a gap d required by a specific crystal bar radius r cannot be satisfied, the value of the crystal bar radius r can be adjusted according to a gap d that the apparatus can reach, so as to achieve perfect crystal growth conditions. Similarly, when a specific crystal bar radius r cannot be obtained (for example, a required crystal bar radius r is too large, and beyond a production range of the growth apparatus), the perfect crystal growth conditions can be achieved at the reachable value of the crystal bar radius r by adjusting the gap d. Alternatively, a corresponding range of the crystal bar radius r is adjusted by adjusting the gap d within a certain range in a similar manner, so as to satisfy the perfect crystal growth conditions.

According to yet another aspect of the disclosure, the disclosure provides a single crystal. The single crystal is prepared through the method described above. Based on that, during production of the above single crystal, a correlation of a temperature gradient G at a solid-liquid interface for crystal growth at a gap d and a crystal bar radius r is quantitatively analyzed in a simple, convenient and quick manner, and a temperature gradient at the solid-liquid interface is obtained. According to the V/G theory, a perfect crystal can be obtained, such that product quality can be improved, production efficiency of the single crystal is improved and production cost is reduced.

In some embodiments, the single crystal is single crystal silicon. The single crystal silicon is prepared through the above method. Based on that, the single crystal silicon at least has the advantages that production cost is low, and a correlation of a temperature gradient G at a solid-liquid interface for crystal growth at a gap d and a crystal bar radius r can be quantitatively analyzed during production in a simple, convenient and quick manner.

The disclosure will be described in detail below with reference to particular examples of the disclosure.

### Example 1

Nine preset values of the gap are selected, that is, d=40 mm, 42.5 mm, 45 mm, 47.5 mm, 50 mm, 52.5 mm, 55 mm, 57.5 mm and 60 mm, totaling 9 sets of data (referred to as G₁-G₉ below), and CGSIM software is used to simulate and obtain a trend curve of temperature gradient distributions at solid-liquid interfaces for crystal growth at different gaps.

Let G=a₇·r⁶+a₆·r⁵+a₅·|r⁴+a₄·r³+a₃·r²+a₂·r+a, and values of a-a₇ are determined at different d values according to the previous trend curve, as shown in Table 1:

TABLE 1

| | a7 | a6 | a5 | a4 |
|---|---|---|---|---|
| d = 40 | 3.3092431644E⁺⁰⁸ | −1.3697513471E⁺⁰⁸ | 2.1381050105E⁺⁰⁷ | −1.5644629046E⁺⁰⁶ |
| d = 42.5 | 3.0645951452E⁺⁰⁸ | −1.2613275417E⁺⁰⁸ | 1.9609118939E⁺⁰⁷ | −1.4303566802E⁺⁰⁶ |
| d = 45 | 3.1451243914E⁺⁰⁸ | −1.3026006642E⁺⁰⁸ | 2.0334560666E⁺⁰⁷ | −1.4866644278E⁺⁰⁶ |
| d = 47.5 | 2.8682204369E⁺⁰⁸ | −1.1883636430E⁺⁰⁸ | 1.8562883739E⁺⁰⁷ | −1.3588031690E⁺⁰⁶ |
| d = 50 | 2.9570138477E⁺⁰⁸ | −1.2248131765E⁺⁰⁸ | 1.9141667801E⁺⁰⁷ | −1.4017372435E⁺⁰⁶ |
| d = 52.5 | 2.7818008656E⁺⁰⁸ | −1.1520439251E⁺⁰⁸ | 1.7998838750E⁺⁰⁷ | −1.3179266222E⁺⁰⁶ |
| d = 55 | 2.5539111718E⁺⁰⁸ | −1.0615071333E⁺⁰⁸ | 1.6621373966E⁺⁰⁷ | −1.2190817573E⁺⁰⁶ |
| d = 57.5 | 2.4364945628E⁺⁰⁸ | −1.0102312128E⁺⁰⁸ | 1.5798140416E⁺⁰⁷ | −1.1584612412E⁺⁰⁶ |
| d = 60 | 2.2999236308E⁺⁰⁸ | −9.5448557978E⁺⁰⁷ | 1.4939020648E⁺⁰⁷ | −1.0966000543E⁺⁰⁶ |

| | a3 | a2 | a |
|---|---|---|---|
| d = 40 | 5.4161090632E⁺⁰⁴ | −6.7510104164E⁺⁰² | 4.0938529490E⁺⁰¹ |
| d = 42.5 | 4.9351926349E⁺⁰⁴ | −6.1250228947E⁺⁰² | 3.9382610166E⁺⁰¹ |
| d = 45 | 5.1336845087E⁺⁰⁴ | −6.4014241749E⁺⁰² | 3.9616368138E⁺⁰¹ |
| d = 47.5 | 4.7024604656E⁺⁰⁴4 | −5.8421414525E⁺⁰² | 3.9098963193E⁺⁰¹ |
| d = 50 | 4.8394115198E⁺⁰⁴ | −6.0167296271E⁺⁰² | 3.8148601220E⁺⁰¹ |
| d = 52.5 | 4.5527786691E⁺⁰⁴ | −5.6510509976E⁺⁰² | 3.7715023463E⁺⁰¹ |
| d = 55 | 4.2219088283E⁺⁰⁴ | −5.2241561164E⁺⁰² | 3.7811340931E⁺⁰¹ |
| d = 57.5 | 4.0117603193E⁺⁰⁴ | −4.9507366669E⁺⁰² | 3.6860005596E⁺⁰¹ |
| d = 60 | 3.8011829103E⁺⁰⁴ | −4.6767371516E⁺⁰² | 3.6485644494E⁺⁰¹ |

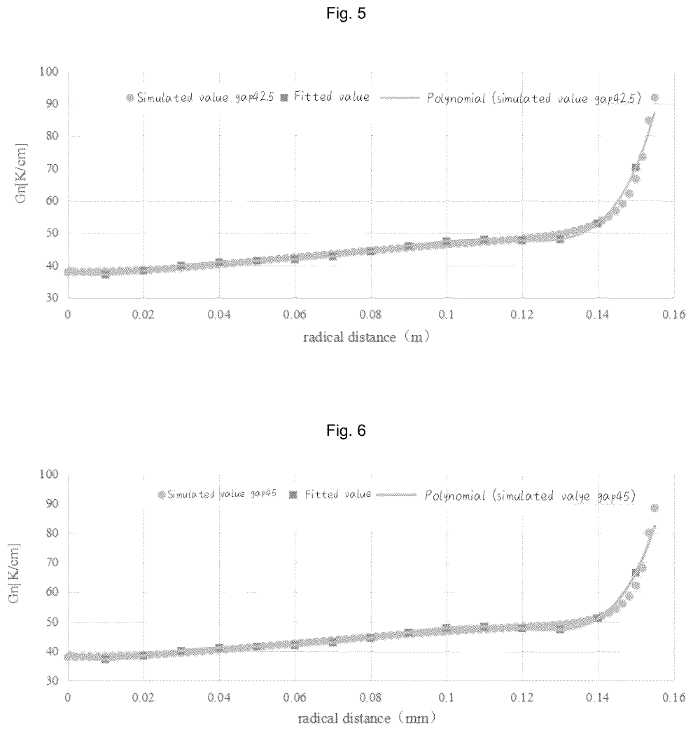

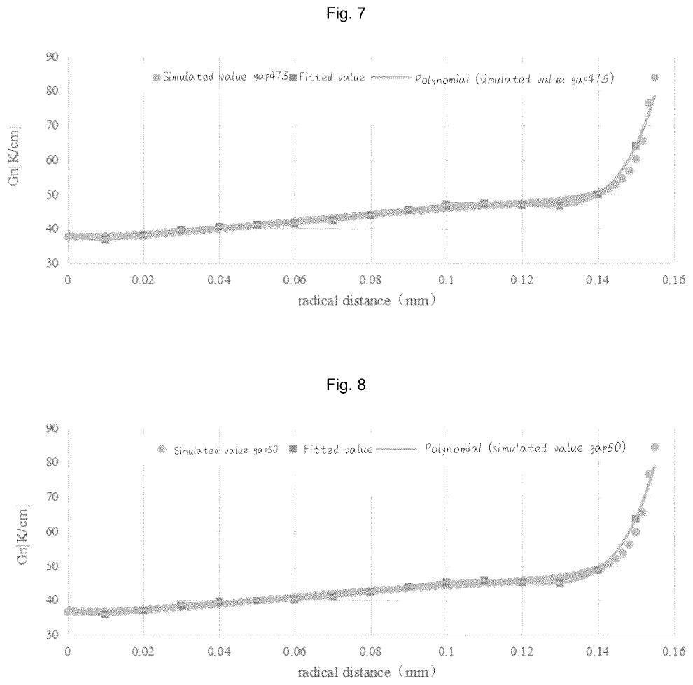

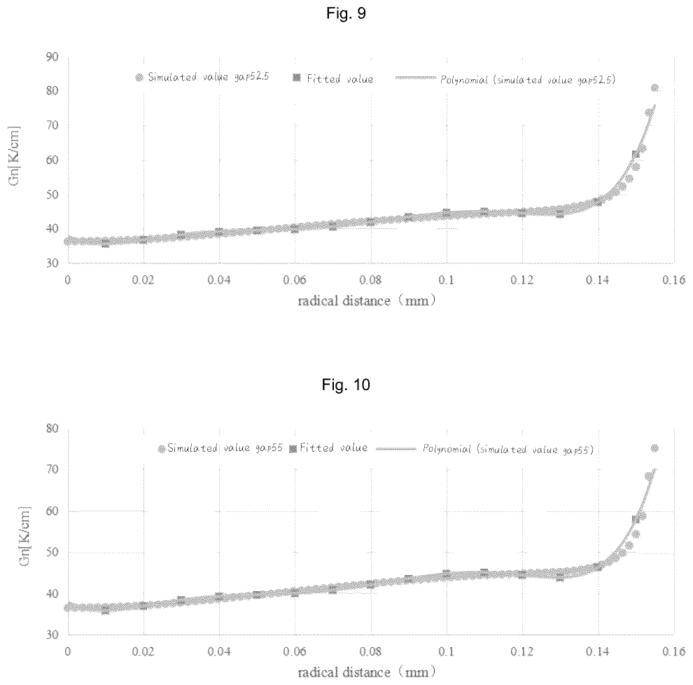

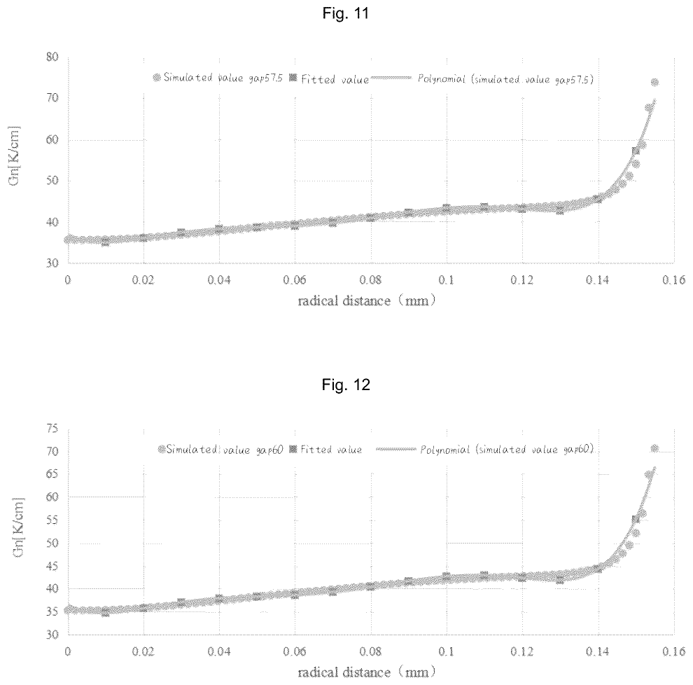

With reference to FIGS. 4-12, with the trend line (expressed as a simulated value gap in the figure) simulated through CGSIM software, a fitted polynomial of the above formula (expressed as the polynomial (the simulated value gap) in the figure), and a polynomial fitting computed value (expressed as the fitted value in the figure) obtained by plugging specific radial coordinates (that is, r value) into G may all be well coincident. Based on that, it may be determined that a fitting effect of the above polynomial with degree six is better. When G is a polynomial of degree six, a coefficient of determination R² is 0.9657-0.9818.

Let a(i)=b₇·d⁶+b₆·d⁵+b₅·d⁴+b₄·d³+b₃·d²+b₂ d+b, i is set as an integer within 1-7 for determining b-b₇ at different gaps:

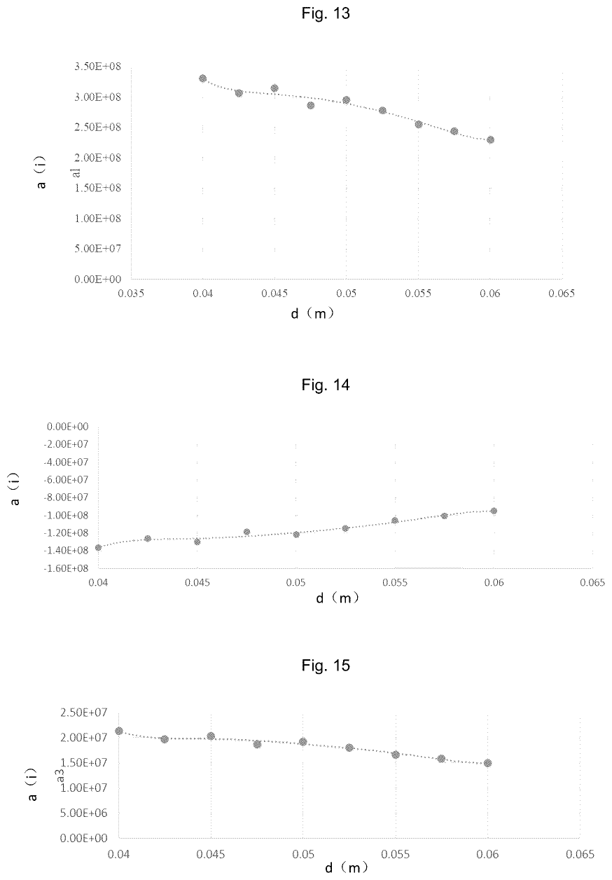

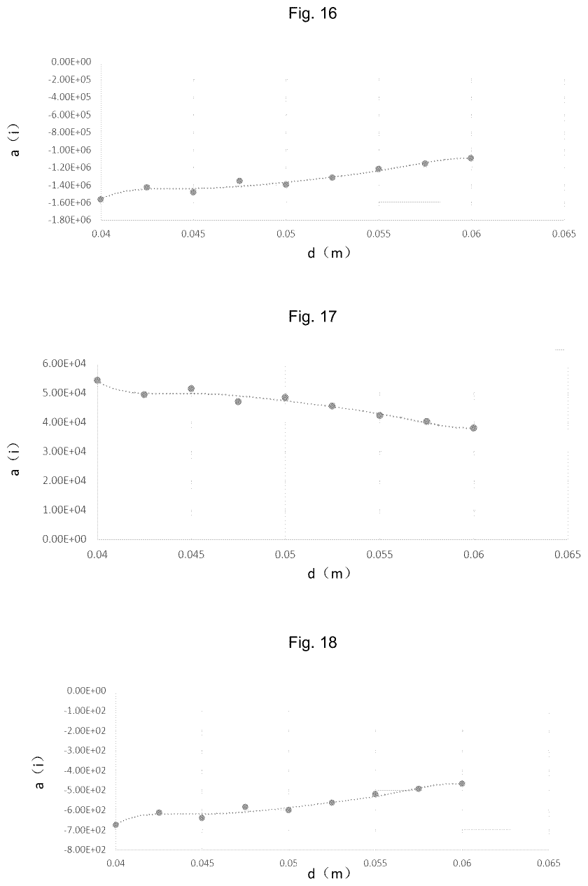

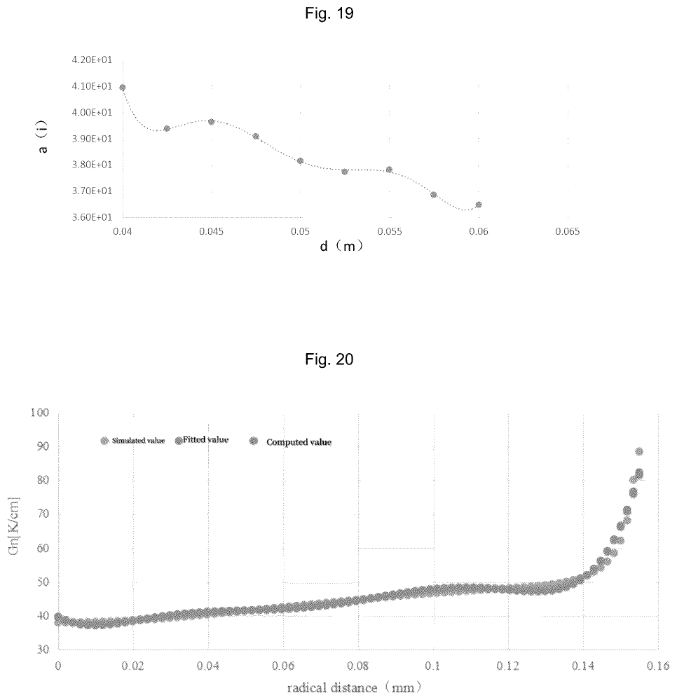

A curve of a₇ with respect to the gap d is drawn by taking a column of data of a₇ in Table 1 above, and the coefficients b₇-b in the a₇ polynomial are determined, and by analogy, the a₆-a polynomial is obtained. With reference to FIGS. 13-19, the obtained coefficients have obvious correlation with the gap (d), and a scatter plot of the coefficients changing with the gap is fitted to obtain a trend polynomial equation of the coefficients changing with the gap. Coefficients of determination R² of the fitted polynomial are all close to 1, that is, when the gap is known, the coefficients of a function for the temperature gradient at the solid-liquid interface at the gap may be obtained, a function of radial coordinates for the temperature gradient at the gap may be determined, and temperature gradients at different radius positions may be computed. The coefficient is positive and decreases as the gap increases, and the coefficient is negative and increases as the gap increases, which are consistent with a law that the interface temperature gradient decreases as the gap increases. Based on that, it indicates that the method according to the disclosure can accurately obtain the relation of the interface temperature gradient to the gap d and radius r.

In order to verify accuracy of fitting and computation of the interface temperature gradient through the method according to the disclosure, relative errors of the coefficients (a₇-a) of the polynomial are computed at the gaps of 45 mm, 50 mm and 55 mm. Relative error=(computation coefficient-fitting coefficient)/fitting coefficient. Specifically, numerical values are plugged into the formula (I) obtained above at gaps of 45 mm, 50 mm and 55 mm, and the coefficients that may be computed are recorded as computation coefficients. The temperature gradient at the interface for crystal growth is simulated according to CGSIM simulation software, the polynomial of the interface temperature gradient with respect to the radial coordinates is fitted through data analysis software, and fitting coefficients are coefficients of the fitted polynomial. With reference to the following table, it can be seen that the relative error of the polynomial coefficient is less than 5% at the gap of 45 mm, 50 mm and 55 mm.

Comparison between the fitting coefficient and a computation coefficient at d=45

| | | | Relative |
|---|---|---|---|
| | Fitting coefficient | Computation coefficient | error |
| a7 | 3.1451243914^{E+08} | 3.0492412935E⁺⁰⁸ | −3.05% |
| a6 | −1.3026006642^{E+08} | −1.2627067691E⁺⁰⁸ | −3.06% |
| a5 | 2.0334560666^{E+07} | 1.9708505788E⁺⁰⁷ | −3.08% |
| a4 | −1.4866644278^{E+06} | −1.4409465118E⁺⁰⁶ | −3.08% |
| a3 | 5.1336845087E⁺⁰⁴ | 4.9799905440E⁺⁰⁴ | −2.99% |
| a2 | −6.4014241749E⁺⁰² | −6.2009415357^{E+02} | −3.13% |
| a | 3.9616368138E⁺⁰¹ | 3.9685285513^{E+01} | 0.17% |

Comparison between the fitting coefficient and a computation coefficient at d=50

| | | | Relative |
|---|---|---|---|
| | Fitting coefficient | Computation coefficient | error |
| a7 | 2.9570138477E⁺⁰⁸ | 2.8930336375E⁺⁰⁸ | −2.16% |
| a6 | −1.2248131765E⁺⁰⁸ | −1.1975054563E⁺⁰⁸ | −2.23% |
| a5 | 1.9141667801E⁺⁰⁷ | 1.8705004500E⁺⁰⁷ | −2.28% |
| a4 | −1.4017372435E⁺⁰⁶ | −1.3694507875E⁺⁰⁶ | −2.30% |
| a3 | 4.8394115198E⁺⁰⁴ | 4.7302768125E⁺⁰⁴ | −2.26% |
| a2 | −6.0167296271E⁺⁰² | −5.8759193125E⁺⁰² | −2.34% |
| a | 3.8148601220E⁺⁰¹ | 3.8125473125E⁺⁰¹ | −0.06% |

Comparison between the fitting coefficient and a computation coefficient at d=55

| | | | Relative |
|---|---|---|---|
| | Fitting coefficient | Computation coefficient | error |
| a7 | 2.5539111718E⁺⁰⁸ | 2.5986102176⁺⁰⁸ | 1.75% |
| a6 | −1.0615071333E⁺⁰⁸ | −1.0795559417E⁺⁰⁸ | 1.70% |
| a5 | 1.6621373966E⁺⁰⁷ | 1.6898132678E⁺⁰⁷ | 1.67% |
| a4 | −1.2190817573E⁺⁰⁶ | −1.2389709640E⁺⁰⁶ | 1.63% |
| a3 | 4.2219088283E⁺⁰⁴ | 4.2882852465E⁺⁰⁴ | 1.57% |
| a2 | −5.2241561164E⁺⁰² | −5.3119986376E⁺⁰² | 1.68% |
| a | 3.7811340931E⁺⁰¹ | 3.7724095561E⁺⁰¹ | −0.23% |

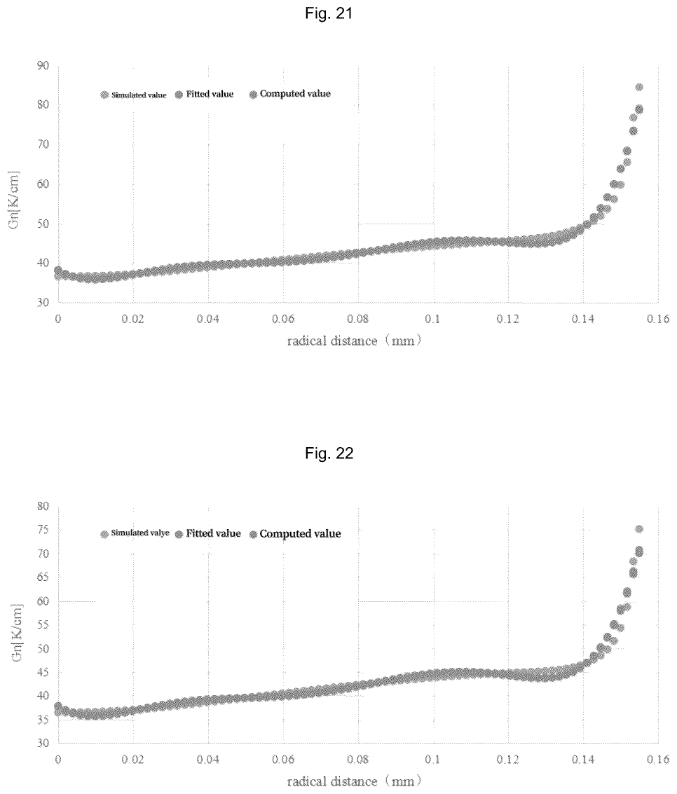

With reference to FIGS. 20-22, a simulated value shown in the figure is the temperature gradient computed through CGSIM software, the fitted value is the temperature gradient computed according to the fitted polynomial, and the computed value is a polynomial computation result obtained through modeling of the temperature gradient function polynomial of the radial coordinates according to the coefficients of the temperature gradient computation polynomial based on the value of the gap. It can be seen from FIGS. 20-22 that the three values are desirable in consistency. Then, it can be concluded that the method can accurately and quantitatively analyze the correlation between the temperature gradient at the interface for crystal growth and the radial coordinates.

After coefficients a in G₁-G₉ and b-b₇ in a(i) at different gaps are obtained, the value range of G required for growth of the perfect crystal may be computed according to a V/G theory.

Then, according to the value range of G and the value range of the gap d that the production apparatus may control, a corresponding value of r within the value range of d is computed and obtained. Based on that, during production, the value of the crystal bar radius r may be determined according to different gaps d, such that r may satisfy the corresponding value.

Alternatively, according to the value range of G and a required value range of the crystal bar radius r, a corresponding value of d within the value range of r is computed and obtained. Based on that, during production, according to different crystal bar radii r, the value of the gap d can be simply inquired and determined, such that the gap d can satisfy the corresponding value by adjusting the apparatus.

For a single crystal furnace during actual production, according to the above method for single crystal growth and the V/G theory for the perfect crystals, a polynomial of G may be obtained on the premise of determining the crystal growth rate in order to obtain a perfect crystal with a larger window, and then the range of the gap d or the crystal bar radius r may be adjusted, such that a margin of process parameters for producing the perfect crystal is increased, and stability of production is guaranteed. Examples of a specific application are as follows:

### Example 2

A method for producing a single crystal of the present invention includes in a specific production application:

S100: a V/G window range that may produce a perfect crystal is determined according to a V/G theory.

Specifically, according to the V/G theory, a corresponding (V/G) range of the window for the perfect crystal is 1.932-2.31*10⁻⁵ cm²·s⁻¹·k⁻¹.

S200: a crystal growth rate V is obtained, and a range of a temperature gradient G at a solid-liquid interface for crystal growth according to the crystal growth rate V and the V/G theory is obtained.

When the single crystal grows at a equal diameter stage, a crystal growth rate is 0.4 mm/min, and a range of a temperature gradient G is 30-35 k·cm⁻¹.

S300: according to the range of the temperature gradient G and a function F(d, r) of the gap d and the crystal bar radius r for the temperature gradient G, a single crystal by determining a gap d or a crystal bar radius r is obtained, and is specifically as follows:

$$G = {a}_{7} \cdot {r}^{6} + {a}_{6} \cdot {r}^{5} + {a}_{5} \cdot {r}^{4} + {a}_{4} \cdot {r}^{3} + {a}_{3} \cdot {r}^{2} + {a}_{2} \cdot r + a \qquad ( III )$$

where the parameters a7, a6, a5, a4, a3, a2 and a in the above formula are polynomials with respect to the gap d, and are specifically as follows:

$$\begin{matrix}{a}_{7} = {b}_{77} \cdot {d}^{6} + {b}_{67} \cdot {d}^{5} + {b}_{57} \cdot {d}^{4} + {b}_{47} \cdot {d}^{3} + {b}_{37} \cdot {d}^{2} + {b}_{27} \cdot d + {b}_{17} \\ {a}_{6} = {b}_{66} \cdot {d}^{5} + {b}_{56} \cdot {d}^{4} + {b}_{46} \cdot {d}^{3} + {b}_{36} \cdot {d}^{2} + {b}_{26} \cdot d + {b}_{16} \\ {a}_{2} = {b}_{22} \cdot d by analogy\end{matrix}$$

When the gap d of the single crystal furnace is 0.045 m, according to trend diagrams of a(i) and the gap d in FIGS. 13-19 that are obtained according to the method for single crystal growth in Example 1, or a relation curve of a(i) and the gap d that is obtained according to the method for single crystal growth in Example 1, a value of a(i) may be directly obtained. Then, the values of a(i) are as follow in turns:

$$\begin{matrix}{a}_{7 =} 3.15 {E}^{+ 08} \\ {a}_{6 =} - 1.3 {E}^{+ 08} \\ {a}_{5 =} 2. {E}^{+ 07} \\ {a}_{4 =} - 1.5 {E}^{+ 06} \\ {a}_{3 =} 5.1 {E}^{+ 04} \\ {a}_{2 =} - 6.4 {E}^{+ 02} \\ a = 3.96 {E}^{+ 01}\end{matrix}$$

The above a(i) is plugged into formula (III) separately, and a polynomial with G=G(r) with respect to the crystal bar radius r merely.

According to the range 30 k·cm⁻¹-35 k·cm⁻¹ of the temperature gradient G of the window for the perfect crystal obtained in S200, the temperature gradient G obtained in S300 is merely a polynomial of the crystal bar radius r and the relation curve of a(i) and the gap d, and the range of the crystal bar radius obtained may be 0.02 m-0.04 m.

### Example 3

A method for producing a single crystal of the present invention includes in a specific production application:

S100: a V/G window range that may produce a perfect crystal is determined according to a V/G theory.

Specifically, according to the V/G theory, a corresponding (V/G) range of the window for the perfect crystal is 0.92-1.1 of (V/G)_{crit}, where (V/G)_{crit}=2.1*10⁻⁵ cm²·s⁻¹·k⁻¹, that is, the (V/G) range is 1.932*10⁻⁵-2.31*10⁻⁵ cm²·s⁻¹·k⁻¹.

S200: a crystal growth rate V is obtained, and a range of a temperature gradient G at a solid-liquid interface for crystal growth according to the crystal growth rate V and the V/G theory is obtained.

When the single crystal grows at a equal diameter stage, a crystal growth rate is 0.55 mm/min, and a range of a temperature gradient G is 40 k·cm⁻¹-50 k·cm⁻¹.

S300: according to the range of the temperature gradient G and a function F(d, r) of the gap d and the crystal bar radius r for the temperature gradient G, a single crystal by determining a gap d or a crystal bar radius r is obtained, and is specifically as follows:

$$G = {a}_{7} \cdot {r}^{6} + {a}_{6} \cdot {r}^{5} + {a}_{5} \cdot {r}^{4} + {a}_{4} \cdot {r}^{3} + {a}_{3} \cdot {r}^{2} + {a}_{2} \cdot r + a \qquad ( III )$$

where the parameters a7, a6, a5, a4, a3, a2 and a in the above formula are polynomials with respect to the gap d, and are specifically as follows:

$$\begin{matrix}{a}_{7} = {b}_{77} \cdot {d}^{6} + {b}_{67} \cdot {d}^{5} + {b}_{57} \cdot {d}^{4} + {b}_{47} \cdot {d}^{3} + {b}_{37} \cdot {d}^{2} + {b}_{27} \cdot d + {b}_{17} \\ {a}_{6} = {b}_{66} \cdot {d}^{5} + {b}_{56} \cdot {d}^{4} + {b}_{46} \cdot {d}^{3} + {b}_{36} \cdot {d}^{2} + {b}_{26} \cdot d + {b}_{16} \\ {a}_{2} = {b}_{22} \cdot d by analogy\end{matrix}$$

According to trend diagrams of temperature gradients G at different gaps and the crystal bar radius r in FIGS. 4-12 that are obtained according to the method for single crystal growth in Example 1, or a relation curve of the temperature gradients G at different gaps and the crystal bar radius r that is obtained according to the method for single crystal growth in Example 1, a range of the gap may be directly obtained.

According to the method for single crystal growth, the crystal bar radius at the equal diameter stage is 0.151 m, and by combining the range of the gap of 40 k·cm⁻¹-50 k·cm⁻¹ obtained in S200 and the relation curve between the temperature gradient G at different gaps and the crystal bar radius r, the range of the temperature gradient is 55 mm-60 mm.

In specification of the description, the specification with reference to terms such as “an instance” and “another instance” means that specific features, structures, materials, or characteristics described in combination with the instance are included in at least one instance of the disclosure. In the description, schematic expressions of the above terms do not necessarily refer to the same instance or example. Further, the particular features, structures, materials or characteristics described can be combined in one or more instances or examples in a suitable manner. In addition, those skilled in the art can combine and group different instances or examples and features in different instances or examples described in the description without contradictions.

Although the instances of the disclosure have been shown and described above, it can be understood that the above instances are exemplary and should not be construed as limitation to the disclosure, and those skilled in the art can make changes, modifications, substitutions and variations to the above instances within the scope of the disclosure.

1. A method for single crystal growth, comprising:
determining a V/G window range that can produce a perfect crystal according to a V/G theory;
obtaining a crystal growth rate V, and obtaining a range of a temperature gradient G at a solid-liquid interface for crystal growth according to the crystal growth rate V and the V/G theory; and
obtaining a single crystal by determining a gap d or a crystal bar radius r according to the range of the temperature gradient G and a function F(d, r) of the gap d and the crystal bar radius r for the temperature gradient G.

2. The method according to claim 1, wherein the function of the gap d and the crystal bar radius r for the temperature gradient G is determined as follows:
performing global simulation computation on heat and mass transfer during crystal growth by Czochralski method at a equal diameter stage, and obtaining temperature gradient distributions at solid-liquid interfaces for crystal growth at a plurality of different gaps separately, wherein the plurality of different gaps are a plurality of preset distances;
obtaining a function of the crystal bar radius r for the temperature gradients G at different gaps separately according to the temperature gradient distributions at the solid-liquid interfaces for crystal growth at the plurality of different gaps;
obtaining, according to the plurality of different gaps and a parameter in a temperature gradient function corresponding to the different gaps, a function of the gaps d for the parameter separately, and
determining the function F(d, r) of the gap d and the radius r for the temperature gradient G, wherein
the gap is an interval between a lower end of a shield and a solid-liquid interface, the temperature gradient is an axial temperature gradient at the solid-liquid interface, and r denotes a crystal bar radius at the equal diameter stage.

3. The method according to claim 1, wherein determining the gap d or the crystal bar radius r comprises:
under the condition that the gap d is a constant value, determining a value range of the crystal bar radius r according to the function F(d, r) and the range of the temperature gradient G, and keeping the crystal bar radius r at the equal diameter stage of the crystal within the value range determined.

4. The method according to claim 3, wherein keeping the crystal bar radius r at the equal diameter stage of the crystal within the value range determined is implemented by adjusting a crystal growth rate of a crystal bar.

5. The method according to claim 2, wherein performing the global simulation computation on heat and mass transfer during the crystal growth by the Czochralski method comprises:
building a two-dimensional numerical-simulation Czochralski method crystal growth model according to a thermal field structure of a Czochralski method crystal growth furnace, and computing and obtaining the temperature gradient distributions at the solid-liquid interfaces for crystal growth at the plurality of different gaps at a et target crystal growth speed, wherein the two-dimensional Czochralski method crystal growth model comprises crystal growth device parameters and process parameters determined according to the set target crystal growth speed.

6. The method according to claim 5, wherein the device parameters comprise:
a quartz crucible, a shield, at least one heater and at least one heat preservation component that are added to the model; or
a graphite crucible, the shield, the at least one heater and the at least one heat preservation component that are added to the model.

7. The method according to claim 5, wherein the process parameters comprise a charging amount, a rotation speed of a crucible and a rotation speed of a crystal bar.

8. The method according to claim 5, wherein computing and obtaining the temperature gradient distributions at the solid-liquid interfaces for crystal growth at the plurality of different gaps comprises:
dividing geometric model of a single crystal furnace to grids, wherein the grids comprises quadrilateral grids, triangular grids and one-dimensional grids configured to perform thermal radiation computation;
computing silicon liquid and gas convection during crystal growth based on Reynolds-averaged Navier-Stokes equations, and computing heat exchange for crystal growth by Czochralski method based on Navier-Stokes equations, a heat conservation equation and a view factor radiation heat exchange method; and
storing a Czochralski method crystal growth variable in a center of a grid cell with a finite volume method, solving a control equation with a discretization method, and reaching the set target crystal growth speed by adjusting power of a heater with a proportional-integral-derivative (PID) algorithm.

9. The method according to claim 1, wherein
determining the gap d or the crystal bar radius r comprises:
under the condition that the crystal bar radius r is a constant value, determining a value range of the gap d according to the function F(d, r) and the range of the temperature gradient G, and keeping the gap d at the equal diameter stage of the crystal within the value range determined.

10. The method according to claim 9, wherein keeping the gap d at the equal diameter stage of the crystal within the value range determined is implemented by adjusting the interval between the lower end of the shield and the solid-liquid interface.

11. The method according to claim 2, wherein the function of the crystal bar radius r for the temperature gradient G is obtained as follows:
$$G = ( a , r ) ,$$
wherein a is a parameter related to the gap d, and the obtaining the function further comprises: determining values of a at different gaps.

12. The method according to claim 11, wherein the function of the crystal bar radius r for the temperature gradient G is a polynomial as follows:
$$G = {a}_{y} \cdot {r}^{( y - 1 )} + {a}_{( y - 1 )} \cdot {r}^{( y - 2 )} + {a}_{( y - 2 )} \cdot {r}^{( y - 3 )} + … + {a}_{( y - x + 1 )} \cdot {r}^{( y - x )} + a ,$$
wherein y is a positive integer greater than 1, and x=y−1.

13. The method according to claim 12, before obtaining the function of the crystal bar radius r for the temperature gradients G at the plurality of different gaps, the method further comprises: determining a number of terms of the polynomial of the crystal bar radius r according to a coefficient of determination of the temperature gradient function, or
a number of the plurality of gaps is not less than 5.

14. (canceled)

15. The method according to claim 11, wherein the function of the gap d for a parameter a is as follows:
$$a = ( b , d ) ,$$
wherein b is a second parameter independent of the gap, and
obtaining the function of the gap d for a parameter a comprises: determining values of b corresponding to different gaps according to the values of a at different gaps and the gap.

16. The method according to claim 15, wherein the parameter a comprises ay-a, the function of the gap d for a parameter a comprises a function of the gap (d) for ay-a obtained, and the function is a polynomial as follows:
$$a ( i ) = {b}_{p} \cdot {d}^{( p - 1 )} + {b}_{( p - 1 )} \cdot {d}^{( p - 2 )} + {b}_{( p - 2 )} \cdot {d}^{( p - 3 )} + … + {b}_{( p - q + 1 )} \cdot {d}^{( p - q )} + b ,$$
wherein p is a positive integer greater than 1, q=p−1, i is a positive integer ranging from y to 1, a coefficient b is a constant independent of the gap, and the coefficient b in the polynomial varies as i changes in value.

17. An apparatus for single crystal growth, comprising:
a furnace body, wherein an inner side of the furnace body is provided with an insulation layer;
a crucible, wherein the crucible is arranged in the furnace body and defines an accommodation space;
a shield, wherein the shield is arranged in the furnace body and above the crucible, and is configured to shield a crystal from heat;
a heater, wherein the heater is arranged between the crucible and the insulation layer;
a pulling apparatus, wherein the pulling apparatus is configured to control a crystal growth rate of a crystal bar; and
a control system, wherein the control system is configured to determine a temperature gradient at a solid-liquid interface for crystal growth according to a method for single crystal growth, and determine a gap and/or a crystal bar radius; wherein
the gap is an interval between a lower end of the shield and the solid-liquid interface, the method comprises:
determining a V/G window range that can produce a perfect crystal according to a V/G theory;
obtaining a crystal growth rate V, and obtaining a range of a temperature gradient G at a solid-liquid interface for crystal growth according to the crystal growth rate V and the V/G theory; and
obtaining a single crystal by determining a gap d or a crystal bar radius r according to the range of the temperature gradient G and a function F(d, r) of the gap d and the crystal bar radius r for the temperature gradient G.

18. A single crystal, prepared through the method according to claim 1.

19. The apparatus for single crystal growth according to claim 17, wherein the function of the gap d and the crystal bar radius r for the temperature gradient G is determined as follows:
performing global simulation computation on heat and mass transfer during crystal growth by Czochralski method at a equal diameter stage, and obtaining temperature gradient distributions at solid-liquid interfaces for crystal growth at a plurality of different gaps separately, wherein the plurality of different gaps are a plurality of preset distances;
obtaining a function of the crystal bar radius r for the temperature gradients G at different gaps separately according to the temperature gradient distributions at the solid-liquid interfaces for crystal growth at the plurality of different gaps;
obtaining, according to the plurality of different gaps and a parameter in a temperature gradient function corresponding to the different gaps, a function of the gaps d for the parameter separately, and
determining the function F(d, r) of the gap d and the radius r for the temperature gradient G, wherein
the gap is an interval between a lower end of a shield and a solid-liquid interface, the temperature gradient is an axial temperature gradient at the solid-liquid interface, and r denotes a crystal bar radius at the equal diameter stage.

20. The apparatus for single crystal growth according to claim 17, wherein determining the gap d or the crystal bar radius r comprises:
under the condition that the gap d is a constant value, determining a value range of the crystal bar radius r according to the function F(d, r) and the range of the temperature gradient G, and keeping the crystal bar radius r at the equal diameter stage of the crystal within the value range determined.

21. The apparatus for single crystal growth according to claim 17, wherein determining the gap d or the crystal bar radius r comprises:
under the condition that the crystal bar radius r is a constant value, determining a value range of the gap d according to the function F(d, r) and the range of the temperature gradient G, and keeping the gap d at the equal diameter stage of the crystal within the value range determined.
